(19) United States
(12) Patent Application Publication
(10) Pub. No.: US 2025/0098097 A1
(43) Pub. Date: Mar. 20, 2025

(54) FULL-MOTION ELECTRONIC HANDWHEEL

(71) Applicant: Min Li, Changshu (CN)

(72) Inventors: Min Li, Changshu (CN); Qian Li, Changshu (CN); Wen Li, Changshu (CN)

(21) Appl. No.: 18/787,878

(22) Filed: Jul. 29, 2024

(30) Foreign Application Priority Data
Sep. 15, 2023 (CN) 202311194460.8

(51) Int. Cl. H05K 7/14; G05G 1/01; H01H 13/14

(52) U.S. Cl. CPC H05K 7/1427; G05G 1/01; H01H 13/14

(57) ABSTRACT

Disclosed is a full-motion electronic handwheel, falling within the field of electronic handwheels. According to the present disclosure, by adding an X-axis button, a Y-axis button, a Z-axis button, a 4-axis button, a multi-axis changeover switch and a general function and full-motion changeover switch to a general electronic handwheel structure, an operator can switch between a 4-axis and a 6-axis via the multi-axis changeover switch, which is convenient for the operator to quickly switch a working mode as required. Meanwhile, through the general function and full-motion changeover switch, the operator can complete various operations only by relying on the electronic handwheel, which simplifies original complicated operations.

### CROSS-REFERENCE TO RELATED APPLICATIONS

This application claims priority of Chinese Patent Application No. 202311194460.8, filed on Sep. 15, 2023, the entire contents of which are incorporated herein by reference.

### TECHNICAL FIELD

The present disclosure belongs to the technical field of electronic handwheels, in particular to a full-motion electronic handwheel.

### BACKGROUND

In the field of automatic control, if a control operation needs to be performed on a product, a coordinate origin needs to be established according to the product firstly, and then control commands are all run starting from the coordinate origin. In this process, the data of the origin needs to be input into each axis coordinate, and at this time, an operator is required to continuously and manually switch between an axis selection knob, a magnification knob and a manual pulse generator of the existing equipment, and this operation mode is very inconvenient for highly integrated automatic control. Therefore, a full-motion electronic handwheel machine is provided.

An electronic handwheel is mentioned in the Chinese patent with a publication number of CN215846867U, which belongs to the technical field of numerical control machine tools, including a housing and a control circuit board. A feeding knob, an axial selection key, a coordinate axis selection knob and a magnification selection knob are arranged on a surface of the housing, and are electrically connected to the control circuit board. A confirmation cancel button is arranged on a side surface of the housing, and is configured to click the confirmation cancel button to determine a coordinate of the touch point when a centering tool touches the workpiece. When centering is performed on the workpiece, the electronic handwheel in the present application is adopted, and the coordinate of the touch point can be determined by directly operating a confirmation cancel button on the electronic handwheel without operating an upper computer, which is very convenient, and can reduce incorrect manipulations and the risk of collision between the workpiece and the centering tool.

During the application process, it is found that although the electronic handwheel in the above application is arranged with an axial selection key, a coordinate axis selection knob and a magnification selection knob, a control circuit in the field of automatic control is generally complicated, and an operator will choose a working mode of 4-axis or 6-axis according to actual situations, and the electronic handwheel in the above application cannot quickly switch the working state as required.

### SUMMARY

An object of the present disclosure is to provide a full-motion electronic handwheel to solve the problems set forth in the above background.

In order to achieve the above object, the present disclosure provides the following technical solutions.

A full-motion electronic handwheel includes:
a handwheel housing, a control circuit board being arranged in the handwheel housing;
an X-axis button, a Y-axis button, a Z-axis button and a 4-axis button, sequentially arranged on one side of the handwheel housing from top to bottom;
a magnification toggle switch, arranged on the other side of the handwheel housing;
a general function and full-motion changeover switch, arranged on the handwheel housing; and
a multi-axis changeover switch, arranged on the handwheel housing and positioned below the general function and full-motion changeover switch.

Preferably, a display screen is arranged at the front of the handwheel housing, and the display screen is positioned at an upper portion of the front of the handwheel housing.

Preferably, a magnification knob and an axis selection knob are juxtaposed at a middle of the front of the handwheel housing.

Preferably, a manual pulse generator is designed at a lower portion of the front of the handwheel housing.

Preferably, the X-axis button, the Y-axis button, the Z-axis button and the 4-axis button are arranged on a right side of the handwheel housing, and four buttons, namely the X-axis button, the Y-axis button, the Z-axis button and the 4-axis button, are integrally arranged in an arc shape along finger ends of a holder.

Preferably, the magnification toggle switch is arranged at an upper portion of a left side of the handwheel housing.

Preferably, the magnification knob, the axis selection knob, the manual pulse generator, the X-axis button, the Y-axis button, the Z-axis button, the 4-axis button, the magnification toggle switch, the display screen, the general function and full-motion changeover switch and the multi-axis changeover switch are electrically connected to the control circuit board in the handwheel housing.

Compared with the prior art, the present disclosure has the following beneficial effects.

According to the present disclosure, by adding an X-axis button, a Y-axis button, a Z-axis button, a 4-axis button, a multi-axis changeover switch and a general function and full-motion changeover switch to a general electronic handwheel structure, an operator can switch between a 4-axis working mode and a 6-axis working mode via the multi-axis changeover switch, which is convenient for the operator to quickly switch a working mode as required. Meanwhile, according to the present disclosure, by arranging the general function and full-motion changeover switch, the operator can freely switch between a general function and a full-motion function via the general function and full-motion changeover switch. In this way, the operator can complete various operations only by relying on the electronic handwheel without leaving the electronic handwheel and the manual pulse generator, so that original complicated operations are simplified, and the labor intensity of the staff can be effectively reduced, thus improving the work efficiency.

### BRIEF DESCRIPTION OF THE DRAWINGS

FIG. 1 is a schematic structural diagram of the front of an electronic handwheel according to the present disclosure;

FIG. 2 is a schematic structural diagram of one side of the electronic handwheel according to the present disclosure;

FIG. 3 is a working schematic diagram of a side button of the electronic handwheel according to the present disclosure;

FIG. 4 is a schematic structural diagram of the other side of the electronic handwheel according to the present disclosure;

FIG. 5 is a schematic diagram of a magnification selection circuit of the electronic handwheel according to the present disclosure;

FIG. 6 is a schematic diagram of a four-axis selection circuit of the electronic handwheel according to the present disclosure;

FIG. 7 is a schematic diagram of a six-axis selection circuit of the electronic handwheel according to the present disclosure; and

FIG. 8 is a schematic diagram of a double-button magnification selection circuit of the electronic handwheel according to the present disclosure.

Reference numerals and denotations thereof: 1—handwheel housing; 2—magnification knob; 3—axis selection knob; 4—manual pulse generator; 5—X-axis button; 6—Y-axis button; 7—Z-axis button; 8—4-axis button; 9—magnification toggle switch; 10—display screen; 11—general function and full-motion changeover switch; 12—multi-axis changeover switch; and 13—X-Y-Z-axis and 4-5-6-axis conversion button.

### DETAILED DESCRIPTION

Technical solutions in the examples of the present disclosure will be described clearly and completely in the following with reference to the attached drawings in the examples of the present disclosure. Obviously, all the described examples are only some, rather than all examples of the present disclosure. Based on the examples in the present disclosure, all other examples obtained by those of ordinary skill in the art without creative efforts belong to the scope of protection of the present disclosure.

### Example 1

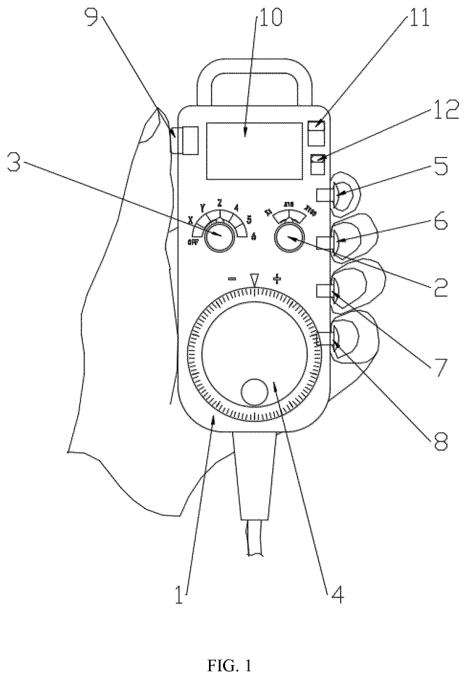

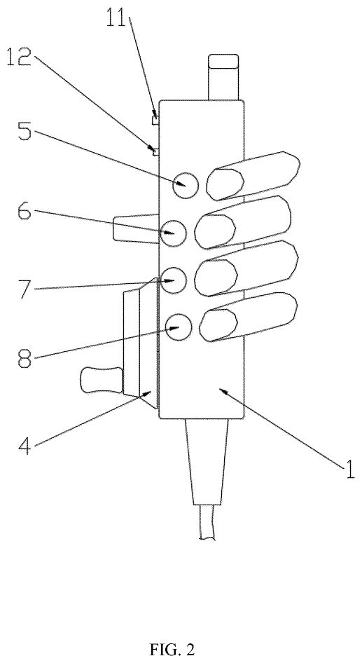

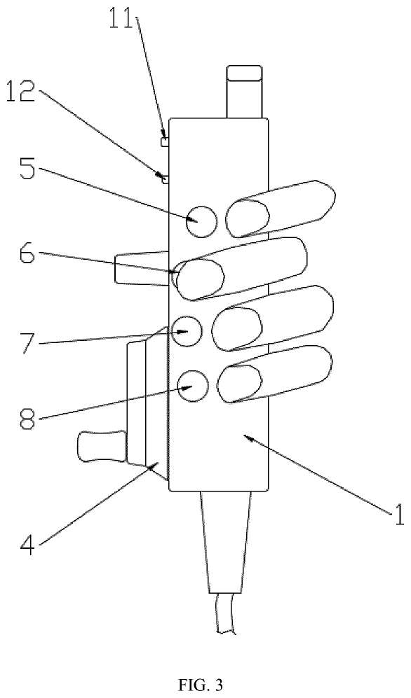

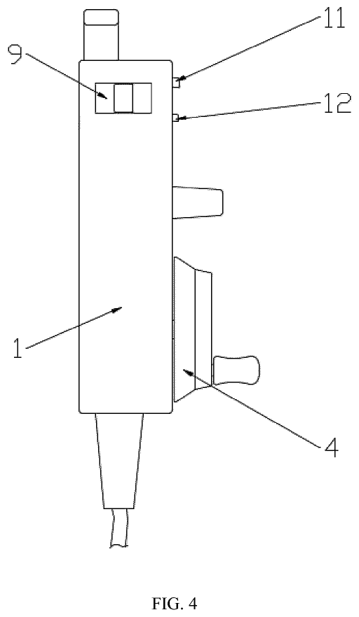

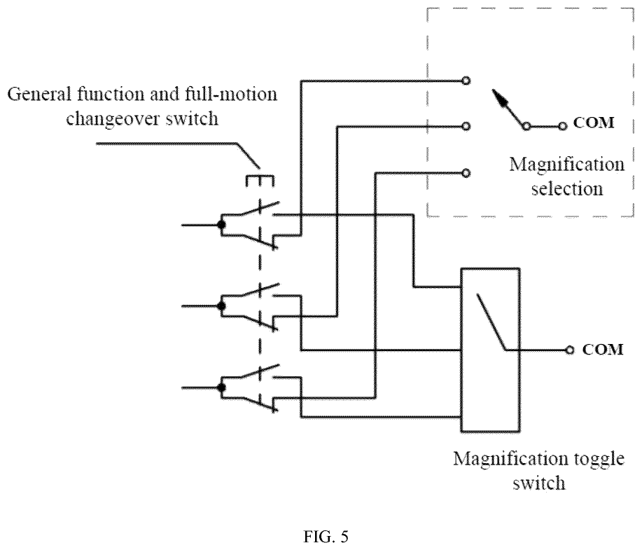

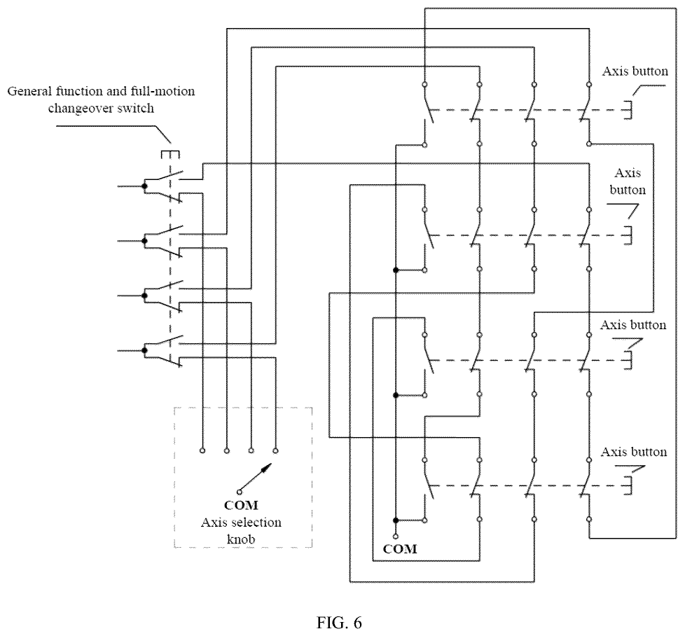

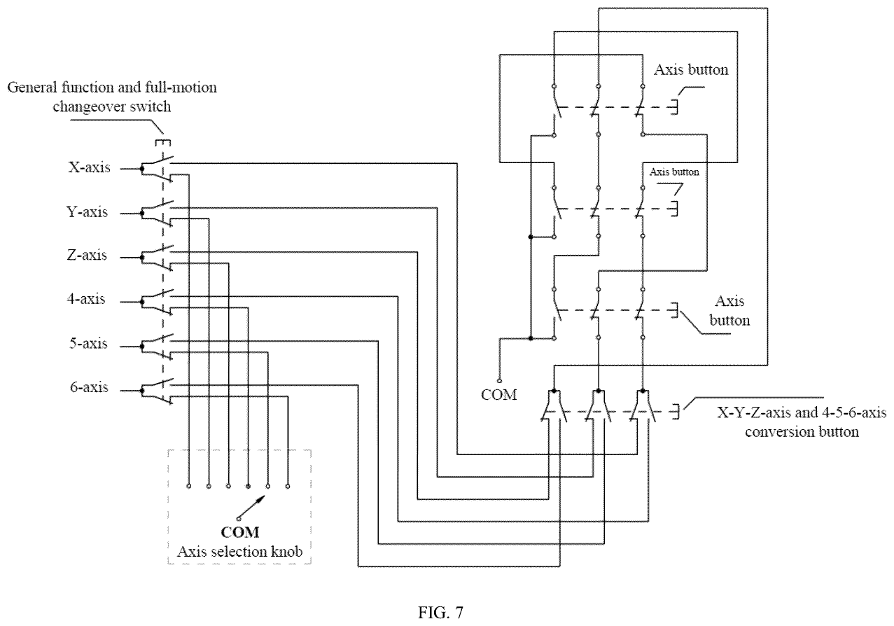

Referring to FIGS. 1-7, a full-motion electronic handwheel includes:
a handwheel housing 1, a control circuit board being arranged in the handwheel housing 1;
an X-axis button 5, a Y-axis button 6, a Z-axis button 7 and a 4-axis button 8, sequentially arranged on one side of the handwheel housing 1 from top to bottom;
a magnification toggle switch 9, arranged on the other side of the handwheel housing 1, the control magnification of the magnification toggle switch 9 including one, ten and one hundred times.
a general function and full-motion changeover switch 11, arranged on the handwheel housing 1, the general function and full-motion changeover switch 11 being capable of realizing the conversion between a general function and a full-motion function; and
a multi-axis changeover switch 12, arranged on the handwheel housing 1 and positioned below the general function and full-motion changeover switch 11, the multi-axis changeover switch 12 being a 4-axis and 6-axis changeover switch.

A display screen 10 is arranged at the front of the handwheel housing 1, and the display screen 10 is positioned at an upper portion of the front of the handwheel housing 1; a magnification knob 2 and an axis selection knob 3 are juxtaposed at a middle of the front of the handwheel housing 1; and a manual pulse generator 4 is designed at a lower portion of the front of the handwheel housing 1.

The X-axis button 5, the Y-axis button 6, the Z-axis button 7 and the 4-axis button 8 are arranged on a right side of the handwheel housing 1, and four buttons, namely the X-axis button 5, the Y-axis button 6, the Z-axis button 7 and the 4-axis button 8, are integrally arranged in an arc shape along finger ends of a holder, which facilitates the operator's four fingers to accurately press the X-axis button 5, the Y-axis button 6, the Z-axis button 7 and the 4-axis button 8 when the operator holds the electronic handwheel with the left hand.

The magnification toggle switch 9 is arranged at an upper portion of a left side of the handwheel housing 1, which facilitates the operator's thumb to press the magnification toggle switch 9.

The magnification knob 2, the axis selection knob 3, the manual pulse generator 4, the X-axis button 5, the Y-axis button 6, the Z-axis button 7, the 4-axis button 8, the magnification toggle switch 9, the display screen 10, the general function and full-motion changeover switch 11 and the multi-axis changeover switch 12 are electrically connected to the control circuit board in the handwheel housing 1.

It can be seen from the above that the operator can hold the handwheel housing 1 with the left hand to realize the conversion between a general function and a full-motion function via the general function and full-motion changeover switch 11, and at the same time, to realize the transformation of working states at 4-axis and 6-axis via the multi-axis changeover switch 12. In the full-motion mode, after holding the electronic handwheel housing 1 with the left hand, the magnification toggle switch 9 can be pressed by the thumb to slide left, middle and right to realize the magnification control of one, ten and one hundred times. The X-axis button 5 can be pressed by the left index finger, the Y-axis button 6 can be pressed by the middle finger, the Z-axis button 7 can be pressed by the ring finger, and the 4-axis button 8 can be pressed by the little finger.

In the 4-axis working state, the multi-axis changeover switch 12 is switched to the 4-axis, and the switch combinations of the four buttons, including the X-axis button 5, the Y-axis button 6, the Z-axis button 7 and the 4-axis button 8, are in a same structure. In operation, the button pressed first takes effect, and the pressed button is invalid when the pressed button is not released.

If there is a need for the 6-axis, a 6-axis state is adjusted to via the multi-axis changeover switch 12. In the 6-axis state, after pressing the single X-axis button 5, the system is in an X-axis state; after pressing the single Y-axis button 6, the system is in a Y-axis state; and after pressing the single Z-axis button 7, the system is in a Z-axis state. The 4-axis button 8 is pressed and then the X-axis button 5 is pressed, the system is in a 4-axis state; the 4-axis button 8 is pressed and then the Y-axis button 6 is pressed, the system is in a 5-axis state; and the 4-axis button 8 is pressed and then the Z-axis button 7 is pressed, the system is in a 6-axis state, so that both the magnification control and the axis selection control can be operated by the fingers of the left hand without leaving the electronic handwheel housing 1, and the right hand only needs to control the manual pulse generator 4, which makes the work smoother. The function of the display screen 10 is to reflect the currently controlled magnification and control the axis to eliminate incorrect manipulations.

The multi-axis changeover switch 12 is canceled as long as the 4-axis is required, and the system defaults to the 4-axis state; and the multi-axis changeover switch 12 is canceled as long as the 6-axis is required, and the system defaults to the 6-axis state.

The position of the 4-axis button 8 is the same as that of an X-Y-Z-axis and 4-5-6-axis conversion button 13.

### Example 2

The example is different from Example 1 in the following technical features.

The magnification toggle switch 9 controls only one contact signal, the specific switching signal being controlled by an internal circuit. Alternatively, a magnification signal may be controlled by two or three button switches instead of the magnification toggle switch 9.

The function changeover is controlled by one or more self-locking interlocked button switches instead of the general function and full-motion changeover switch 11.

Each of the four button switches, namely the X-axis button 5, the Y-axis button 6, the Z-axis button 7 and the 4-axis button 8, controls a contact signal, and the specific switching signal is controlled by an internal circuit.

Under the general function, the magnification toggle switch 9, the X-axis button 5, the Y-axis button 6, the Z-axis button 7, the 4-axis button 8 have no effect.

Under the full-motion function, the magnification knob 2 and the axis selection knob 3 have no effect.

### Example 3

The example is different from Example 1 and Example 2 in the following technical features.

Referring to FIGS. 1-7, when the electronic handwheel is arranged with a 6-axis selection circuit, the general function and full-motion changeover switch 11 being not pressed, an axis selection signal passes through a normally closed point of the general function and full-motion changeover switch 11 to a COM point, then the axis selection knob works, the general function is activated, and the full-motion function has no effect due to the signal to a normally open point.

After the general function and full-motion changeover switch 11 is pressed, the function is not effective after the axis selection signal of the general function is disconnected, and the function is activated after the full-motion signal is connected, for example, when the X-Y-Z-axis and 4-5-6-axis conversion button 13 is not pressed, the selection functions of the X axis, Y axis and Z axis are activated. When the X-axis button is pressed, the signal is sent from the general function and full-motion changeover switch 11 via a normally closed point of the axis conversion button and a normally closed point of the Z-axis button and a normally closed point of the Y-axis button to a closed point of the X-axis to COM, the selection of X-axis is completed, and the other two functions are the same. If the X-axis button is not released at this time and the Y-axis button is pressed, the Y-axis signal is disconnected via the normally closed contact in the X-axis button, and the X-axis signal is also disconnected via the normally closed point of the Y-axis button, so that incorrect manipulations do not occur due to the disconnection of both signals.

If the X-Y-Z-axis and 4-5-6-axis conversion button 13 is pressed, the selection functions of the 4-axis, 5-axis and 6-axis are activated, and the selection functions of X-axis, Y-axis and Z-axis have no effect due to the disconnection of the normally closed points, so that the selection buttons of the three axes can achieve the selection functions of six axes.

### Example 4

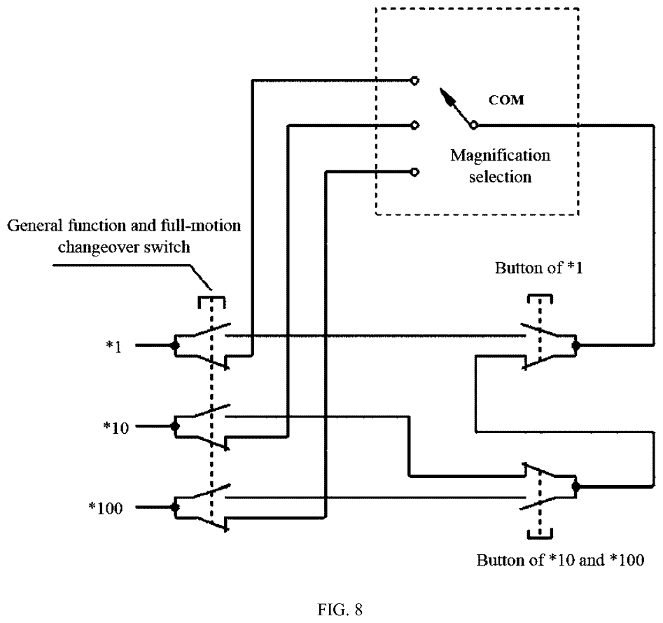

Referring to FIG. 8, when the general function and full-motion changeover switch 11 is pressed, the full-motion function is activated; and a *10 magnification signal works by default from a normally closed end of a magnification button of *10 and *100 to a normally closed end of a magnification button of *1 to a CDM end.

When the magnification button of *10 and *100 is pressed, the normally closed point of the *10 magnification signal is disconnected, and a *100 magnification signal is connected and sent to COM through the normally closed point of the magnification button of *1; and the *100 magnification signal works.

When the magnification button of *1 is pressed, the magnification signals of *10 and *100 are all disconnected, and a *1 magnification signal is sent to COM through the magnification button of *1; and the *1 magnification signal works.

While examples of the present disclosure have been shown and described, it will be understood by those skilled in the art that various changes, modifications, substitutions and alterations may be made herein without departing from the principles and spirit of the present disclosure, the scope of which is defined by the appended claims and equivalents thereof.

1. A full-motion electronic handwheel, comprising:
a handwheel housing (1), a control circuit board being arranged in the handwheel housing (1);
an X-axis button (5), a Y-axis button (6), a Z-axis button (7) and a 4-axis button (8), sequentially arranged on one side of the handwheel housing (1) from top to bottom;
a magnification toggle switch (9), arranged on the other side of the handwheel housing (1);
a general function and full-motion changeover switch (11), arranged on the handwheel housing (1); and
a multi-axis changeover switch (12), arranged on the handwheel housing (1) and positioned below the general function and full-motion changeover switch (11).

2. The full-motion electronic handwheel according to claim 1, wherein a display screen (10) is arranged at the front of the handwheel housing (1), and the display screen (10) is positioned at an upper portion of the front of the handwheel housing (1).

3. The full-motion electronic handwheel according to claim 1, wherein a magnification knob (2) and an axis selection knob (3) are juxtaposed at a middle of the front of the handwheel housing (1).

4. The full-motion electronic handwheel according to claim 1, wherein a manual pulse generator (4) is designed at a lower portion of the front of the handwheel housing (1).

5. The full-motion electronic handwheel according to claim 1, wherein the X-axis button (5), the Y-axis button (6), the Z-axis button (7) and the 4-axis button (8) are arranged on a right side of the handwheel housing (1), and four buttons, namely the X-axis button (5), the Y-axis button (6), the Z-axis button (7) and the 4-axis button (8), are integrally arranged in an arc shape along finger ends of a holder.

6. The full-motion electronic handwheel according to claim 1, wherein the magnification toggle switch (9) is arranged at an upper portion of a left side of the handwheel housing (1).

7. The full-motion electronic handwheel according to claim 3, wherein the magnification knob (2), the axis selection knob (3), the manual pulse generator (4), the X-axis button (5), the Y-axis button (6), the Z-axis button (7), the 4-axis button (8), the magnification toggle switch (9), the display screen (10), the general function and full-motion changeover switch (11) and the multi-axis changeover switch (12) are electrically connected to the control circuit board in the handwheel housing (1).

8. The full-motion electronic handwheel according to claim 1, wherein while holding a handwheel body with one hand, fingers can simultaneously control: the magnification toggle switch (9) and axes selection buttons.
